(19) United States
(12) Patent Application Publication
(10) Pub. No.: US 2021/0233955 A1
(43) Pub. Date: Jul. 29, 2021

(54) DISPLAY DEVICE

(71) Applicant: Japan Display Inc., Tokyo (JP)

(72) Inventor: Osamu ITOU, Tokyo (JP)

(73) Assignee: Japan Display Inc., Tokyo (JP)

(21) Appl. No.: 17/155,084

(22) Filed: Jan. 22, 2021

(30) Foreign Application Priority Data
Jan. 27, 2020 (JP) 2020-010862

(51) Int. Cl. H01L 27/15; H01L 33/38; H01L 33/26; H01L 33/24

(52) U.S. Cl. CPC H01L 27/156; H01L 33/24; H01L 33/26; H01L 33/38

(57) ABSTRACT

According to one embodiment, a display device comprises a display portion comprising a plurality of pixels. Each of the pixels comprises an anode, a cathode, and a light-emitting diode disposed between the anode and the cathode. The light-emitting diode comprises an emitting layer and a resistive layer partly overlapping the emitting layer in planar view. A width w of a region of the emitting layer which does not overlap the resistive layer and a thickness d of the light-emitting diode satisfy w/d>1.

### CROSS-REFERENCE TO RELATED APPLICATIONS

This application is based upon and claims the benefit of priority from Japanese Patent Application No. 2020-010862, filed Jan. 27, 2020, the entire contents of which are incorporated herein by reference.

### FIELD

Embodiments described herein relate generally to a display device.

### BACKGROUND

A light-emitting diode (LED) display device using LEDs which are self-luminous elements has been known as a display device. Recently, a display device in which extremely small light-emitting diodes referred to as micro-LEDs or mini-LEDs are mounted on an array substrate (hereinafter referred to as a micro-LED display device) has been developed as a high-definition display device.

Since a large number of chip-like micro-LEDs are mounted in a display region, unlike a conventional liquid crystal display or organic EL display, a micro-LED display can easily achieve both high definition and high contrast and receives attention as a next-generation display device.

### BRIEF DESCRIPTION OF THE DRAWINGS

FIG. 1 is a plan view of a display device of the present embodiment.

FIG. 2 is an enlarged plan view of a display portion DP.

FIG. 3 is an equivalent circuit of a pixel PX.

FIG. 4A is a cross-sectional schematic view of the pixel including a driving thin-film transistor DTR.

FIG. 4B is an enlarged cross-sectional view of a vicinity of a light-emitting diode LED.

FIG. 5 is a plan view of a region in which a resistive layer RL and an emitting layer EM overlap each other in FIG. 4B.

FIG. 6 is a schematic view showing a resistance value and a current of the light-emitting diode LED.

FIG. 7A is a schematic view showing light emission of the light-emitting diode LED.

FIG. 7B is a schematic view showing light emission of the light-emitting diode LED.

FIG. 8A is a cross-sectional view showing a modification example of the light-emitting diode LED.

FIG. 8B is a cross-sectional view showing a modification example of the light-emitting diode LED.

FIG. 8C is a cross-sectional view showing a modification example of the light-emitting diode LED.

FIG. 9 is a cross-sectional view showing another modification example of the light-emitting diode LED.

FIG. 10A is a plan view showing another modification example of the light-emitting diode LED.

FIG. 10B is a plan view showing another modification example of the light-emitting diode LED.

FIG. 11A is a plan view showing another modification example of the light-emitting diode LED.

FIG. 11B is a plan view showing another modification example of the light-emitting diode LED.

FIG. 11C is a plan view showing another modification example of the light-emitting diode LED.

FIG. 12A is a cross-sectional view showing another modification example of the light-emitting diode LED.

FIG. 12B is a cross-sectional view showing another modification example of the light-emitting diode LED.

FIG. 12C is a cross-sectional view showing another modification example of the light-emitting diode LED.

FIG. 13 is a cross-sectional view showing a light-emitting diode LED of a comparative example.

FIG. 14A is a cross-sectional view showing an equipotential surface in the light-emitting diode LED of the embodiment.

FIG. 14B is a cross-sectional view showing an equipotential surface in the light-emitting diode LED of the comparative example.

FIG. 15 is a cross-sectional view showing a light-emitting diode LED of another comparative example.

### DETAILED DESCRIPTION

In general, according to one embodiment, a display device comprises a display portion comprising a plurality of pixels. Each of the pixels comprises an anode, a cathode, and a light-emitting diode disposed between the anode and the cathode. The light-emitting diode comprises an emitting layer and a resistive layer partly overlapping the emitting layer in planar view. A width w of a region of the emitting layer which does not overlap the resistive layer and a thickness d of the light-emitting diode satisfy w/d>1.

According to the present embodiment, a micro-LED display device having improved in reproducibility of low grayscale can be provided.

Embodiments of the present invention will be described hereinafter with reference to the accompanying drawings. The disclosure is a mere example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes and the like, of the respective parts are illustrated schematically in the drawings, rather than as an accurate representation of what is implemented. However, such schematic illustration is merely exemplary, and in no way restricts the interpretation of the invention. In addition, in the specification and drawings, elements similar to those described in connection with preceding drawings are denoted by the same reference numbers, and detailed description of them is omitted unless necessary.

A display device according to one embodiment will be described in detail with reference to the drawings.

In the present embodiment, a first direction X, a second direction Y and a third direction Z are orthogonal to one another. However, these directions may cross one another at an angle other than 90 degrees. A direction toward the point of an arrow indicating the third direction Z is defined as up or above, and a direction on an opposite side to the direction toward the point of the arrow indicating the third direction Z is defined as down or below.

In addition, when described as “the second member above the first member” and “the second member below the first member”, the second member may be in contact with the first member or apart from the first member. In the latter case, the third member may be interposed between the first member and the second member. On the other hand, when described as “the second member over the first member” and “the second member under the first member”, the second member is in contact with the first member.

Furthermore, an observation position from which the display device DSP is observed is assumed to be located on the point side of the arrow indicating the third direction Z, and viewing from this observation position toward an XY-plane defined by the first direction X and the second direction Y is referred to as planar view.

### Embodiment

FIG. 1 is a plan view of the display device of the present embodiment. A display device DSP shown in FIG. 1 includes a substrate SU. A display portion DP, peripheral circuits PFC on the periphery of the display portion DP, connection portions CN on the periphery of the peripheral circuits PFC are disposed on the substrate SU. External driving elements are connected via the connection portions CN.

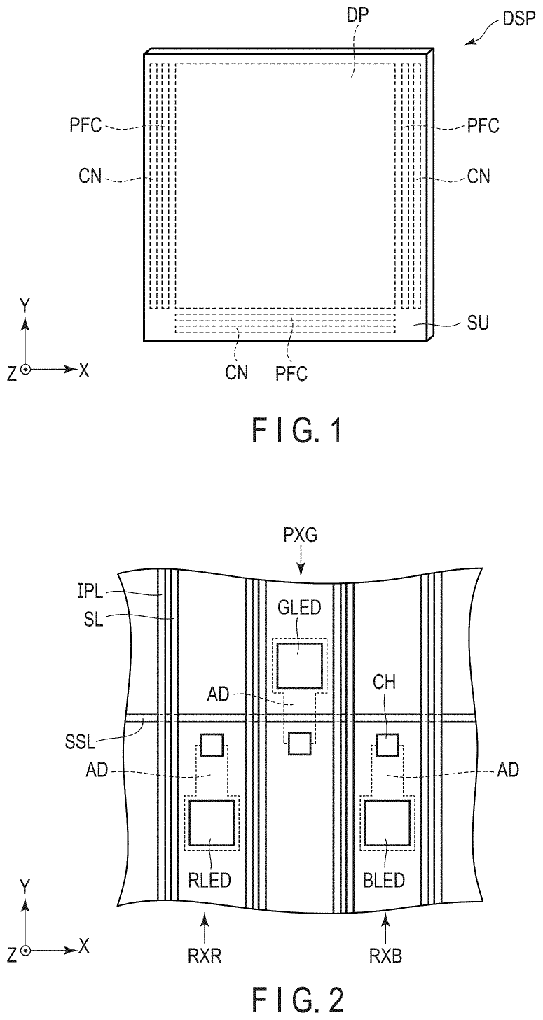

FIG. 2 is an enlarged plan view of the display portion DP. The display portion DP includes a plurality of pixels. The display portion DP includes a signal scanning line SSL, a signal line SL, a current supply line IPL, contact holes CH, a red light-emitting diode RLED, a green light-emitting diode GLED and a blue light-emitting diode BLED.

Among the pixels, a pixel PXR includes the red light-emitting diode RLED, a pixel PXG includes the green light-emitting diode GLED, and a pixel PXB includes the blue light-emitting diode BLED. The pixel PXR, the pixel PXG and the pixel PXB emit red light, green light and blue light, respectively. Note that the pixel PXR, the pixel PXG and the pixel PXB are referred to as the first pixel, the second pixel and the third pixel, respectively, in the present specification.

In the present embodiment, the red light-emitting diode RLED, the green light-emitting diode GLED and the blue light-emitting diode BLED are micro-LEDs whose longest sides have a length of less than or equal to 100 μm in planar view. The display device DSP of the present embodiment is a micro-LED display device including micro-LEDs in pixels. In addition, light-emitting diode LEDs are generally referred to as mini-LEDs when their longest sides have a length of greater than 100 μm in planar view. The present embodiment can be applied to both a display device using micro-LEDs and a display device using mini-LEDs.

As shown in FIG. 2, the signal line SL and the current supply line IPL extend parallel in the second direction Y and are disposed paired with each other. The signal scanning line SSL extends in the first direction X and crosses the signal line SL and the current supply line IPL.

The contact hole CH of each pixel PX (the pixel PXR, the pixel PXG, the pixel PXB) is disposed inside a lattice formed by the pair of signal line SL and current supply line IPL and the signal scanning line SSL. An anode AD on which the light-emitting diode LED of the pixel PX (the red light-emitting diode RLED, the green light-emitting diode GLED, the green light-emitting diode BLED) is mounted is electrically connected to a transistor of an equivalent circuit of the pixel PX which will be described later via the contact hole CH.

In FIG. 2, the red light-emitting diode RLED and the blue light-emitting diode BLED are each disposed opposed to the signal scanning line SSL across the contact hole CH. The green light-emitting diode GLED is disposed opposed to the contact hole CH across the signal scanning line SSL.

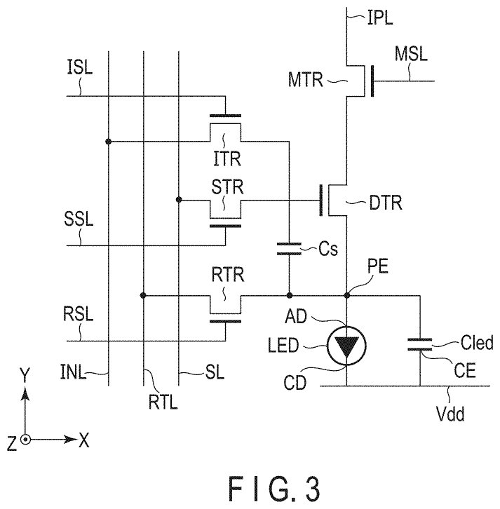

FIG. 3 is the equivalent circuit of the pixel PX. The pixel PX includes a signal thin-film transistor STR, an initialization thin-film transistor ITR, a reset thin-film transistor RTR, a driving thin-film transistor DTR, a current measurement thin-film transistor MTR, a storage capacitance Cs, and an element capacitance Cled.

The current measurement thin-film transistor MTR is opened and closed by a current measurement scanning line MSL, and forms a circuit for current measurement in the pixel PX. The signal thin-film transistor STR is opened and closed by the signal scanning line SSL, and controls opening and closing of the driving thin-film transistor DTR by a voltage supplied from the signal line SL. The initialization thin-film transistor ITR is opened and closed by an initialization scanning line ISL, and controls opening and closing of the driving thin-film transistor DTR by a voltage supplied from an initialization line INL. The reset thin-film transistor RTR is opened and closed by a reset scanning line RSL, and applies a reverse bias voltage supplied from a reset line RTL to the light-emitting diode LED. The driving thin-film transistor DTR is opened and closed by the signal thin-film transistor STR and the initialization thin-film transistor ITR, and supplies a current of the current supply line IPL to the light-emitting diode LED.

In addition, as shown in FIG. 3, the pixel electrode PE is electrically connected to a drain of the driving thin-film transistor DTR, the anode AD of the light-emitting diode LED, one of electrode of the storage capacitance Cs, and one of electrode of the element capacitance Cled. The storage capacitance Cs is formed between a gate and a source of the driving thin-film transistor DTR. The element capacitance Cled which is an internal capacitance of the light-emitting diode LED is connected to a low-potential power supply Vss via a common electrode CE. A cathode CD of the light-emitting diode LED is connected to the low-potential power supply Vss.

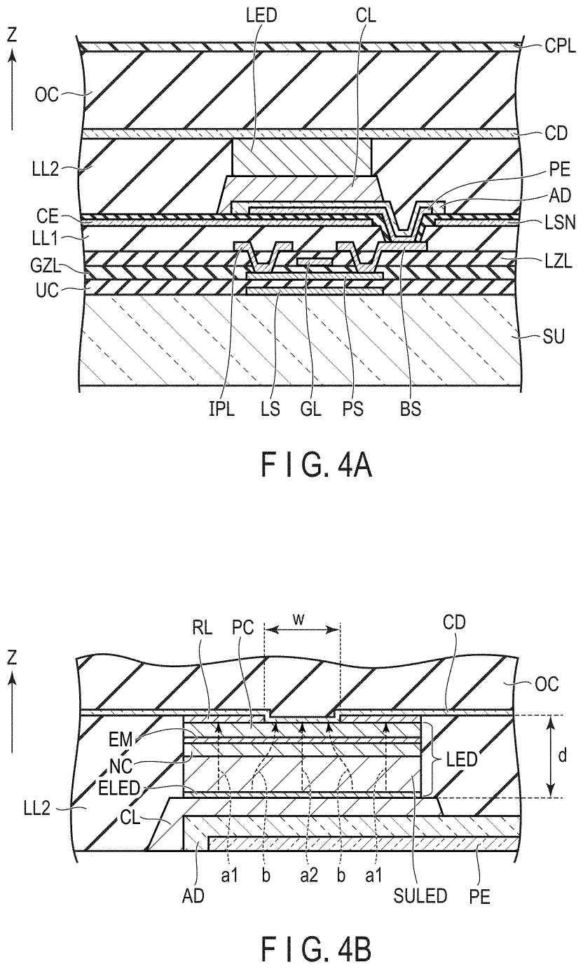

FIGS. 4A and 4B are a cross-sectional schematic view of the pixel including the driving thin-film transistor DTR and an enlarged cross-sectional view of the vicinity of the light-emitting diode LED, respectively. As shown in FIG. 4A, a light-shielding layer LS, an undercoat layer UC, a polysilicon layer PS, a gate insulating film GZL, a scanning line GL, an interlayer insulating film LZL, the current supply line IPL, a base BS, a first planarization layer LL1, the common electrode CE, a capacitor nitride film LSN, the pixel electrode PE, the anode AD, a connection layer CL, the light-emitting diode LED, a light ejection layer LPL, a second planarization layer LL2, the cathode CD, an overcoat layer OC, and a circular polarization plate CPL are stacked in order from closest to the substrate SU.

The scanning line GL of the driving thin-film transistor DTR is formed such that drain lines of the signal thin-film transistor STR and the initialization thin-film transistor ITR are merged.

The substrate SU is, for example, a borosilicate glass having a thickness of 100 μm. The light-shielding layer LS is a molybdenum tungsten alloy film having a thickness of 50 nm. The light-shielding layer LS is a laminated body of a silicon nitride layer and a silicon oxide layer, and the thicknesses of the respective layers are 100 nm and 150 nm.

The polysilicon layer PS is formed such that an amorphous silicon layer is made polycrystalline by a laser annealing method, and has a thickness of 50 nm. The gate insulating film GZL is a silicon oxide layer having a thickness of 100 nm, and the signal line SL is a molybdenum tungsten alloy film having a thickness of 300 nm.

The interlayer insulating film LZL is a laminated body of a silicon oxide layer and a silicon nitride layer, and the thicknesses of the respective layers are 350 nm and 375 nm. The current supply line IPL and the base BS are three-layer laminated films of titanium, aluminum and titanium located in the same layer, and the thicknesses of the respective layers are 100 nm, 400 nm and 200 nm.

The first planarization layer LL1 and the second planarization layer LL2 are organic insulating films, and have a thickness of 2 μm and a thickness of 10 μm, respectively. The common electrode CE, the pixel electrode PE and the cathode CD are indium tin oxide films, and have a thickness of 50 nm, a thickness of 50 nm and a thickness of 100 nm, respectively. The capacitor nitride film LSN is a silicon nitride layer formed at low temperature, and has a thickness of 120 nm.

The anode AD is a laminated body of indium tin oxide, silver and indium tin oxide, and the connection layer CL is a silver paste. The overcoat layer OC is a laminated body of a silicon nitride film having a thickness of 200 nm and an organic insulating film having a thickness of 10 μm.

The light-emitting diode LED shown in FIG. 4B includes a resistive layer RL, a p-type clad layer PC, an emitting layer EM, an n-type clad layer NC, a light-emitting diode substrate SULED, and a light-emitting diode electrode ELED from the top.

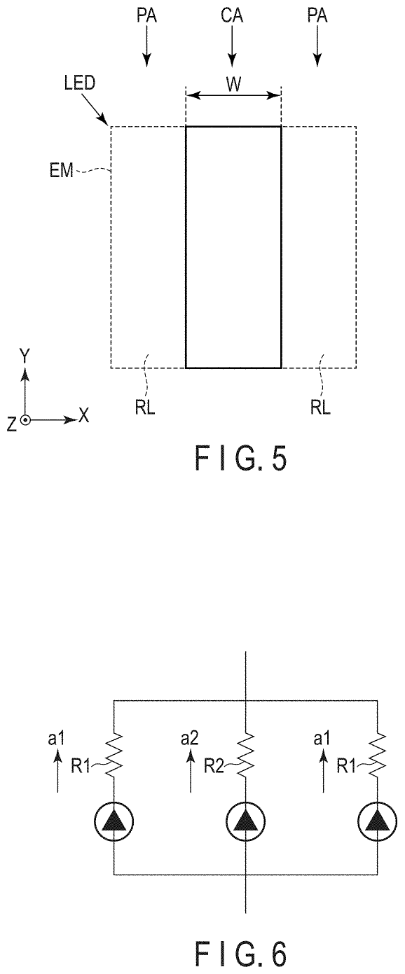

FIG. 5 is a plan view of a region in which the resistive layer RL and the emitting layer EM overlap each other in FIG. 4B. Note that the layers disposed between the resistive layer RL and the emitting layer EM in the third direction Z are omitted in FIG. 5. As shown in FIG. 5, a region CA in which the resistive layer RL is absent and a region in which the resistive layer RL is present are disposed on the emitting layer EM. In other words, a region in the resistive layer RL which overlaps the emitting layer EM is the region PA, and a region in the resistive layer RL which does not overlap the emitting layer EM is the region CA. With respective to the emitting layer EM, the region CA is sandwiched between two regions PA in planar view and is disposed in a rectangular shape. The details of the region CA and the region PA will be described later.

The emitting layer EM constituting the blue light-emitting diode BLED is indium gallium nitride in which the composition ratio between indium and gallium is 0.2:0.8, the p-type clad layer and the n-type clad layer are gallium nitride, and the light-emitting diode substrate SULED is carbide nitride.

The emitting layer EM constituting the green light-emitting diode GLED is indium gallium nitride in which the composition ratio between indium and gallium is 0.45:0.55, the p-type clad layer and the n-type clad layer are gallium nitride, and the light-emitting diode substrate SULED is silicon carbide.

The emitting layer EM constituting the red light-emitting diode RLED is aluminum gallium indium phosphide in which the composition ratio among aluminum, gallium and indium is 0.225:0.275:0.5, the p-type clad layer and the n-type clad layer are aluminum indium phosphide, and the light-emitting diode substrate SULED is gallium arsenide.

The resistive layer RL, the light-emitting diode substrate SULED, the light-emitting diode electrode ELED are the same in the light-emitting diode LEDs of the respective colors, and are group III-IV compound semiconductor, sapphire and aluminum, respectively.

In each light-emitting diode LED, the respective layers are formed on the light-emitting diode substrate SULED, the light-emitting diode substrate SULED is thinned, and the light-emitting diode electrode ELED is formed at the bottom. After that, it is cut into a square shape and is disposed on the connection layer CL. When a silver paste is used as the connection layer CL, the connection layer CL deforms according to a temporary pressure and adheres to the light-emitting diode LED, and electrical continuity is established. Alternatively, aluminum which is the same material as the light-emitting diode electrode ELED may be used as the connection layer CL. In this case, by heating after disposing the light-emitting diode electrode LED, the light-emitting diode LED can be integrated with the light-emitting diode electrode ELED, and electrical continuity can be established.

The maximum emission wavelengths of the red light-emitting diode RLED, the green light-emitting diode GLED and the blue light-emitting diode BLED are 645 nm, 530 nm and 450 nm, respectively.

In the light-emitting diode LED of FIG. 4B, the light-emitting diode substrate SULED is thinned. In this case, current mainly flows along the thickness direction between the cathode CD and the anode AD, and diffraction of current is reduced. Dashed lines shown in FIG. 4B are currents flowing from the anode AD to the cathode CD. Currents a (currents a1 and a2) are currents flowing straight along the thickness direction, and a current b is a current involving diffraction. In the light-emitting diode LED shown in FIG. 4B, the main current is the current a.

As shown in FIG. 4B, the resistive layer RL is distributed in some parts, and the light-emitting diode LED includes a part in which the resistive layer RL is present and a part in which the resistive layer RL is absent. The current a1 is a current flowing the part in which the resistive layer RL is present, and the current a2 is a current flowing in the part in which the resistive layer RL is absent.

The reduction of the current b involving diffraction shown in FIG. 4B is influenced not only by a thickness d of the light-emitting diode LED but also by a width w of a region in which the resistive layer RL is absent, and the width w of the region in which the resistive layer RL is absent should preferably be greater than or equal to half the thickness d of the light-emitting diode LED. Furthermore, when w/d>1, the current b involving diffraction can be sufficiently reduced.

FIG. 6 is a schematic view showing the resistance value and current of the light-emitting diode LED. The resistance value of the region in which the resistive layer RL is present is referred to as R1, and the resistance value of the region in which the resistive layer RL is absent is referred to as R2. As shown in FIG. 5, the light-emitting diode LED has different series-connected resistance values R1 and R2 in the region in which the resistive layer RL is present and the region in which the resistive layer RL is absent (R1>R2). This is equivalent to saying that a plurality of light-emitting diodes LEDs having different operation characteristics are connected in parallel.

A micro-LED exhibits clear threshold characteristics when it is current driven. Therefore, luminance-current characteristics on a low grayscale side become steep, and low grayscale cannot be sufficiently reproduced in some cases. However, the light-emitting diode LED of the present embodiment includes the region in which the resistive layer RL is present and the region in which the resistive layer RL is absent, and is equivalent to a plurality of different light-emitting diodes LED connected in parallel.

Therefore, for example, even if the voltage-current characteristics of an individual light-emitting diode LED is too steep, an effect similar to that when a plurality of light-emitting diodes LEDs having different voltage-current characteristics are simultaneously turned on can be obtained. Therefore, sharpness of the voltage-current characteristics of the light-emitting diode LED can be moderated in the present embodiment.

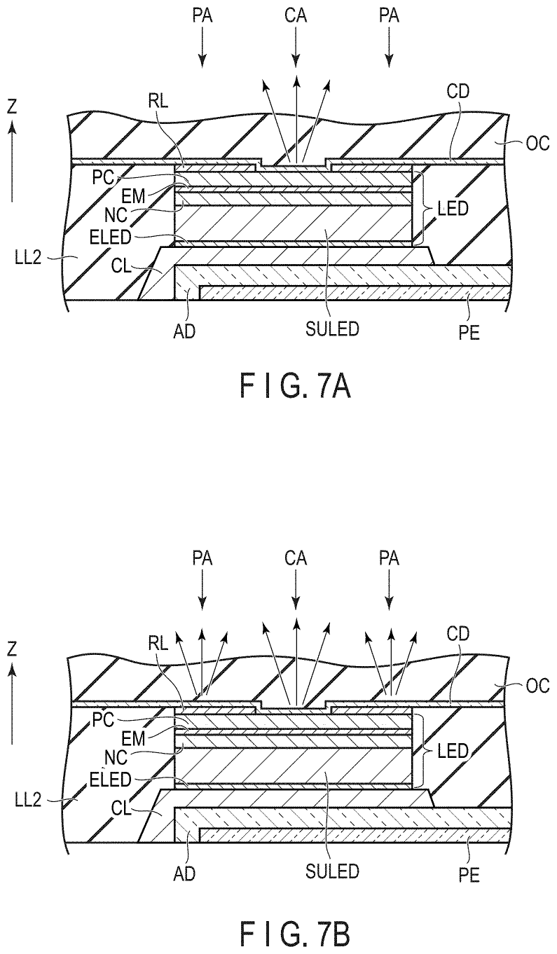

FIGS. 7A and 7B are schematic views showing light emission of the light-emitting diode LED. Although not shown in the drawing, the light-emitting diode LED does not emit light when a voltage applied to the driving thin-film transistor DTR does not reach a threshold value. When current supply from the driving thin-film transistor DTR starts and the applied voltage reaches the threshold value in the region CA in which the resistive layer RL is absent, as shown in FIG. 7A, the region CA in which the resistive layer RL is absent emits light first. The resistance value of the region CA is the above-described resistance value R2.

Then, when the applied voltage reaches the threshold value in the region PA in which the resistance layer RL is present, as shown in FIG. 7B, the region PA in which the resistive layer RL is present emits light. The resistance value of the region PA is the above-described resistance value R1. The region CA in which the resistance layer RL is absent reaches the maximum emission luminance earlier than the region PA in which the resistance layer RL is present.

When the applied voltage further increases and the current value supplied from the driving thin-film transistor DTR increases, the region PA also reaches the maximum emission luminance.

In the light-emitting diode LED shown in FIGS. 7A and 7B, the area of the region CA is less than the area of the region PA. The region CA having a small area and not including the resistance layer RL emits light from a lower current value. Then, when the current value increases, the region PA having a large area and including the resistive layer RL emits light. Accordingly, the grayscale reproducibility of the low grayscale range improves.

For example, AlGaInP-based group III-IV compound semiconductor can be used as the resistive layer RL. Alternatively, the resistive layer RL can be made more resistive by adding ion species and forming reverse matching with a clad layer close to it. For example, in FIG. 4B, the clad layer close to the resistive layer RL is the p-type clad layer PC, and the resistive layer RL can be made more resistive by adding minus ions to group III-IV compound semiconductor and forming an n-type semiconductor layer.

In addition, in place of the above-described semiconductor, a transparent conductive layer which is made more resistive by increasing an oxygen component ratio in a transparent electrode material such as indium tin oxide (ITO) or indium zinc oxide (IZO) can be used as the resistive layer RL.

As described above, according to the present embodiment, a display device having improved in reproducibility of low grayscale can be obtained.

### Modification Example 1

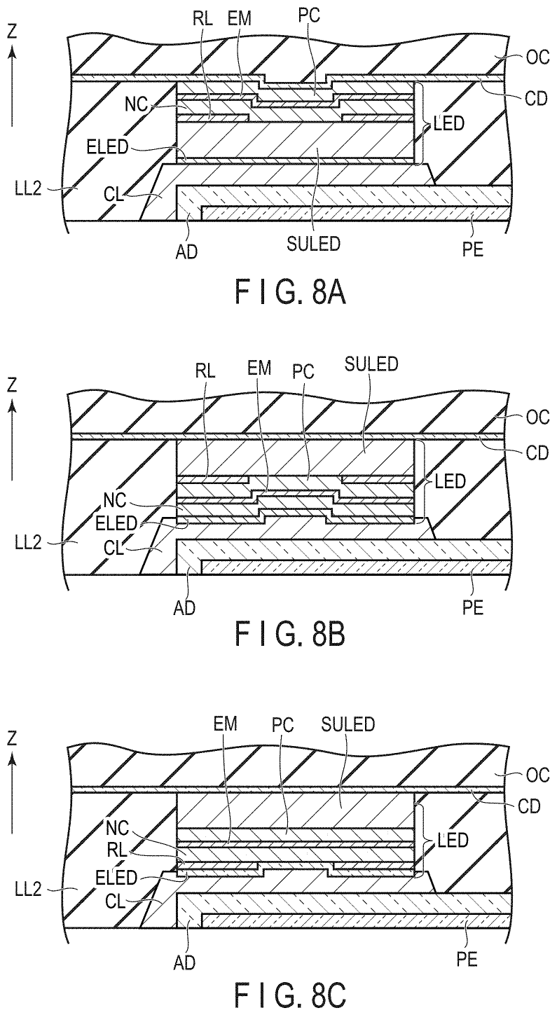

FIGS. 8A and 8B are cross-sectional views showing a modification example of the light-emitting diode LED in the present embodiment. The modification example shown in FIGS. 8A and 8B is different from the configuration example shown in FIGS. 4A and 4B in that the position of the resistive layer RL in the third direction Z is changed.

FIG. 8A shows an example where the resistive layer RL is disposed in the under layer of the n-type clad layer NC in the light-emitting diode LED.

In the light-emitting diode LED shown in FIG. 8A, as compared with the light-emitting diode LED shown in

FIG. 4B, the resistive layer RL is closer to the anode AD, and the current component flowing around to the region in which the resistive layer RL is absent can be further reduced.

In FIG. 8B, the stacking order of the light-emitting diode LED in the third direction Z is the light-emitting diode electrode ELED, the n-type clad layer NC, the emitting layer EM, the p-type clad layer PC, the resistive layer RL and the light-emitting diode substrate SULED. In other words, the light-emitting diode LED of FIG. 8B is formed such that, after the n-type clad layer NC and the p-type clad layer PC are stacked in reverse order on the light-emitting diode substrate SULED, the light-emitting diode LED itself is disposed upside down.

In the light-emitting diode LED shown in FIG. 8B, as compared with the light-emitting diode LED shown in FIG. 8A, the resistive layer RL is even closer to the anode AD, and the current component flowing around so as to avoid the resistive layer RL can be further reduced.

In FIG. 8C, the stacking order of the light-emitting diode LED in the third direction Z is the light-emitting diode electrode ELED, the resistive layer RL, the n-type clad layer NC, the emitting layer EM, the p-type clad layer PC and the light-emitting diode substrate SULED.

In the light-emitting diode LED shown in FIG. 8C, as compared with the light-emitting diode LED shown in FIG. 8B, the resistive layer RL is even closer to the anode AD, and the current component flowing around so as to avoid the resistive layer RL can be further reduced.

### Modification Example 2

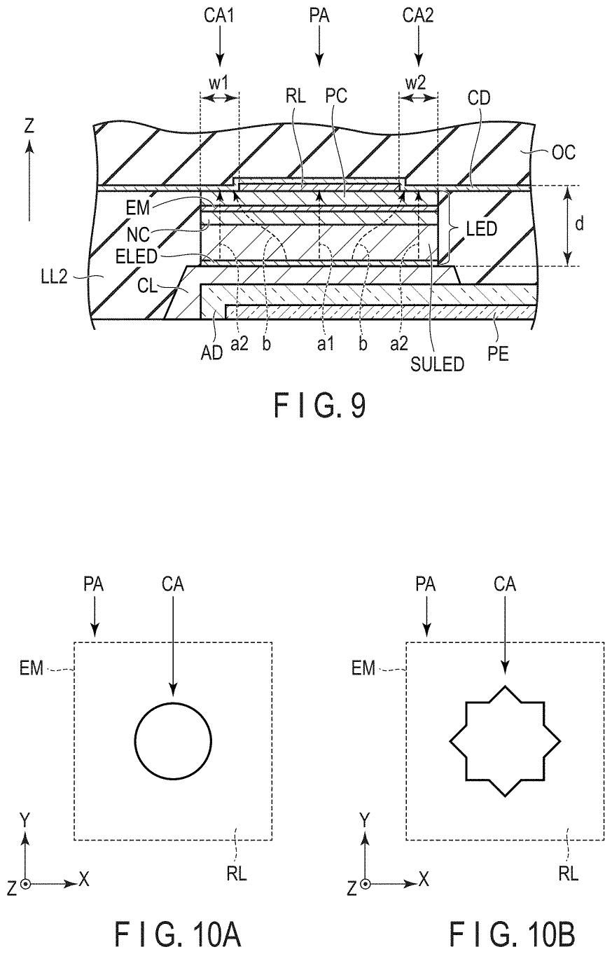

FIG. 9 is a cross-sectional view showing another modification example of the light-emitting diode LED in the present embodiment. The modification example shown in FIG. 9 is different from the configuration example shown in FIG. 7 in that the resistive layer RL is disposed on a central side of the light-emitting diode LED.

In the light-emitting diode LED shown in FIG. 9, the region PA in which the resistive layer RL is present is disposed sandwiched between regions CA1 and CA2 in which the resistive layer RL is absent. Since the resistive layer RL shown in FIG. 9 has a simpler planar shape than the structure shown in FIG. 7, the resistive layer RL can be formed more easily. The shape in planar view of the resistive layer of FIG. 9 is a rectangular shape as is the case of FIG. 5.

In addition, when the widths of the regions CA1 and CA2 shown in FIG. 9 are referred to as w1 and w2, respectively, the width w of the region in which the resistive layer RL is absent is the sum of w1 and w2, that is, w=w1+w2. Also in this case, when w/d>1, the current b flowing around to the region in which the resistive layer RL is absent can be reduced as is the case of FIG. 8. Accordingly, the effect of improving the grayscale reproducibility of the low grayscale range can be obtained also in the present modification example.

As described above, according to the present modification example, a display device having improved in reproducibility of low grayscale can be obtained.

### Modification Example 3

FIGS. 10A and 10B are plan views showing another modification example of the light-emitting diode LED in the present embodiment.

The modification example shown in FIGS. 10A and 10B is different from the configuration example shown in FIG. 5 in the shape of the region in which the resistive layer RL is absent in planar view.

FIGS. 10A and 10B show an example in which the shape in planar view of the region CA in which the resistive layer RL is absent is a circular shape and an example in which the shape in planar view of the region CA is a polygonal shape other than a rectangular shape, respectively.

The circular region CA shown in FIG. 10A has an advantage over the configuration example shown in FIG. 5 in that emitted light from the emitting layer EM spreads more uniformly. Although the shape of the region CA is a perfect circle in FIG. 10A, it is not limited to this. The shape of the region CA may be an ellipse or the like.

The polygonal region CA shown in FIG. 10B has an advantage over the configuration example shown in FIG. 5 in that emitted light from the emitting layer EM spreads more uniformly for a longer distance. Although the shape of the region CA is a hexadecagon in FIG. 10B, it is not limited to this. The shape of the region CA may be another polygon, more specifically, a triangle or a polygon with the same or more sides than a pentagon.

As described above, according to the present modification example, a display device having improved in reproducibility of low grayscale can be obtained.

### Modification Example 4

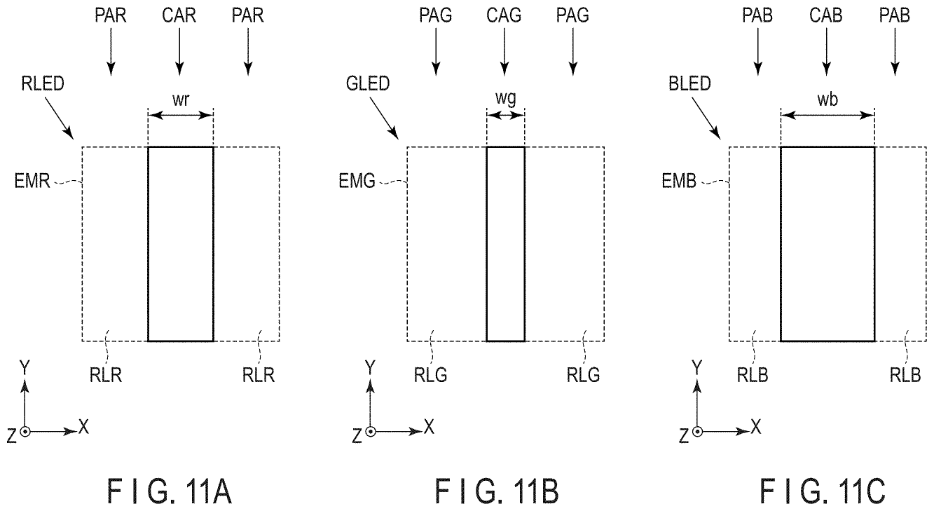

FIG. 11 is a plan view showing another modification example of the light-emitting diode LED in the present embodiment. The modification example shown in FIG. 11 is different from the configuration example shown in FIG. 5 in that the area of the region in which the resistive layer is absent in planar view is different according to an emitted color.

In FIG. 11, the emitting layer of the red light-emitting diode RLED is referred to as an emitting layer EMR, the resistive layer is referred to as a resistive layer RLR, the region in which the resistive layer RLR is absent is referred to as a region CAR, the region in which the resistive layer RLR is present is referred to as a region PAR, and the width of the region CAR is referred to as a width wr.

In addition, in FIG. 11, the emitting layer of the green light-emitting diode GLED is referred to as an emitting layer EMG, the resistive layer is referred to as a resistive layer RLG, the region in which the resistive layer RLG is absent is referred to as a region CAG, the region in which the resistive layer RLG is present is referred to as a region PAG, and the width of the region CAG is referred to as a width wg.

Furthermore, in FIG. 11, the emitting layer of the blue light-emitting diode BLED is referred to as an emitting layer EMB, the resistive layer is referred to as a resistive layer RLB, the region in which the resistive layer RLB is absent is referred to as a region CAB, the region in which the resistive layer RLB is present is referred to as a region PAB, and the width of the region CAB is referred to as a width wb.

In the example shown in FIG. 11, the region CAR of the red light-emitting diode RLED, the region CAG of the green light-emitting diode GLED, the region CAB of the blue light-emitting diode BLED are set such that the area of the region CAB is the largest and the area of the region CAG is the smallest. In other words, the area of the region CAR is smaller than the region CAB but larger than the region CAG.

By setting the area of the region CAG of the green light-emitting diode GLED having high visibility to the smallest and setting the area of the region CAB of the blue light-emitting diode BLED having low visibility to the largest as described above, variations in luminance according to colors can be suppressed.

In the present modification example, the region CAR, the region CAG and the region CAB are rectangles having the same long side length. Therefore, in order to change the areas of the regions, the widths may be changed. That is, the width wr of the red light-emitting diode RLED, the width wg of the green light-emitting diode GLED and the width wb of the blue light-emitting diode BLED are set such that the width wb is the largest and the width wg is the smallest (wb>wr>wg). In other words, the width wr is less than the width wb but greater than the width wg.

As described above, according to the present modification example, a display device having improved in reproducibility of low grayscale can be obtained.

### Modification Example 5

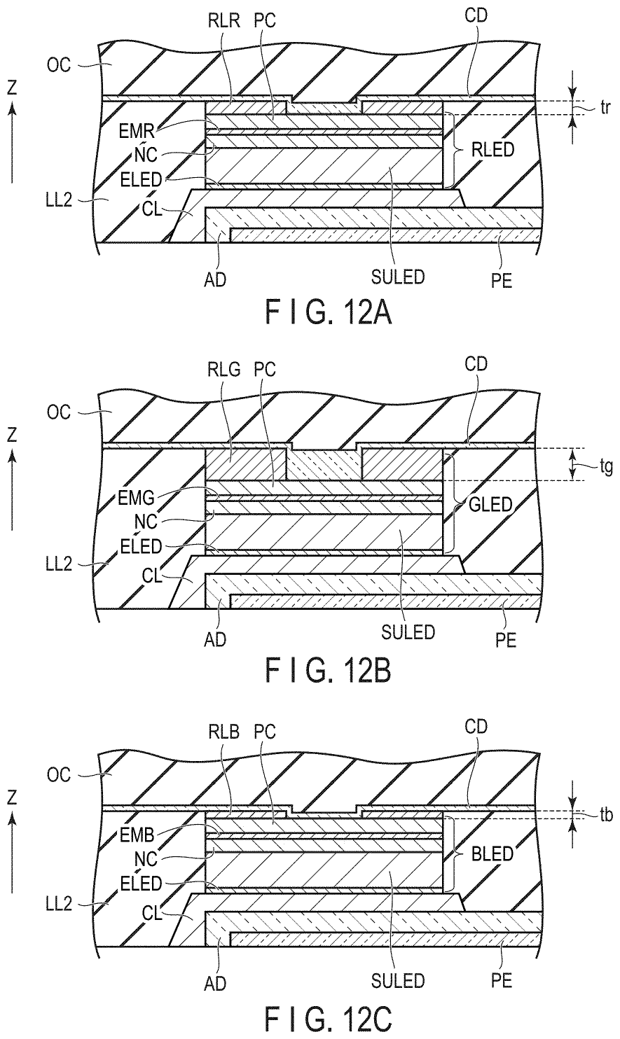

FIG. 12 is a cross-sectional view showing another modification example of the light-emitting diode LED of the present embodiment. The modification example shown in FIG. 12 is different from the configuration example shown in FIG. 5 in that the thickness of the resistive layer in sectional view is different according to an emitted color.

In FIG. 12, the thickness of the resistive layer RLR of the red light-emitting diode RLED is referred to as a thickness tr, the thickness of the resistive layer RLG of the green light-emitting diode GLED is referred to as a thickness tg, and the thickness of the resistive layer RLB of the blue light-emitting diode BLED is referred to as a thickness tb.

In the example shown in FIG. 12, the thickness tr of the resistive layer RLR, the thickness tg of the resistive layer RLG and the thickness tb of the resistive layer RLB are set such that the thickness tb is the smallest and the thickness tg is the largest (tg>tr>tb). In other words, the thickness tr is less than the thickness tg but greater than the thickness tb.

By setting the thickness tb of the resistive layer RLB of the blue light-emitting diode BLED having low visibility to the smallest and setting the thickness tg of the resistive layer RLG of the green light-emitting diode GLED having high visibility to the largest as described above, variations in luminance according to colors can be suppressed.

As described above, according to the present modification example, a display device having improved in reproducibility of low grayscale can be obtained.

### Comparative Example 1

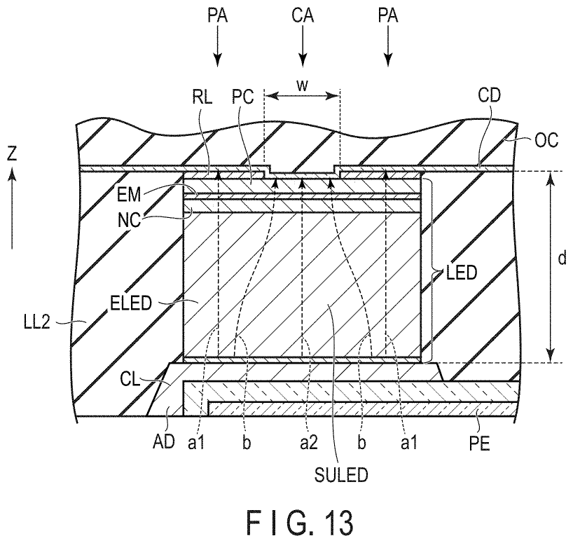

FIG. 13 is a cross-sectional view showing a light-emitting diode LED of a comparative example. In the light-emitting diode LED shown in FIG. 13, the light-emitting diode substrate SULED is not thinned. In FIG. 13, therefore, the width w of the region CA in which the resistive layer RL is absent and the thickness d of the light-emitting diode LED is w/d<1.

When the thickness of the light-emitting diode substrate SULED is large, the gap between the anode AD and the cathode CD increases, accordingly. Therefore, of the current flowing from the anode AD toward the cathode CD, the current b involving diffraction so as to avoid the region PA in which the resistive layer RL increases. Accordingly, the current a1 flowing where the resistive layer RL is present decreases. When the current a1 flowing where the resistive layer RL is present decreases, the current contributing to the light emission of the emitting layer EM is mainly the current a2 passing the region PA in which the resistive layer RL is absent. Therefore, the effect described in FIG. 6 of when the light-emitting diodes LEDs having different voltage-current characteristics are simultaneously turned on cannot be obtained in the present comparative example.

As described above, the light-emitting diode LED of the present comparative example is close to a single light-emitting diode and does not produce an effect of improving the grayscale reproducibility of a low grayscale range.

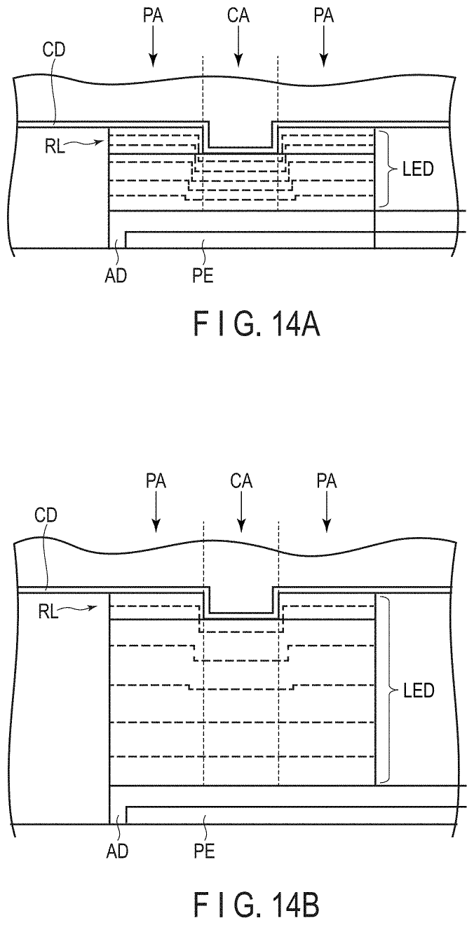

FIGS. 14A and 14B are cross-sectional views showing an equipotential surface of the light-emitting diode LED of the above-described embodiment and an equipotential surface of the light-emitting diode LED of the present comparative example, respectively. FIG. 14A shows an equipotential surface of the light-emitting diode LED shown in FIG. 4B, and FIG. 14B shows an equipotential surface of the light-emitting diode LED shown in FIG. 13.

As shown in FIG. 14A, when the thickness of the light-emitting diode LED is small with respect to the thickness of the resistive layer RL, a difference in electric field distribution between the region PA in which the resistive layer RL is present and the region CA in which the resistive layer RL is absent is large. Therefore, when the current value is changed, the region CA in which the resistive layer RL is absent emits light first, and the region PA in which the resistive layer RL is present emits light next.

Consequently, as shown in FIG. 14A, the reproducibility of low grayscale can be improved in the display device having the light-emitting diode LED of the present embodiment.

On the other hand, as shown in FIG. 14B, when the thickness of the light-emitting diode LED is too large with respect to the thickness of the resistive layer RL, a difference in electric field distribution between the region PA in which the resistive layer RL is present and the region CA in which the resistive layer RL is absent is small. Therefore, when the current value is changed, light is emitted almost simultaneously in the region PA in which the resistive layer RL is present and the region CA in which the resistive layer RL is absent.

If the thickness of the resistive layer RL is too large, the region PA in which the resistive layer RL is present does not emit light. In this case, the only region which emits light is the region CA in which the resistive layer RL is absent.

### Comparative Example 2

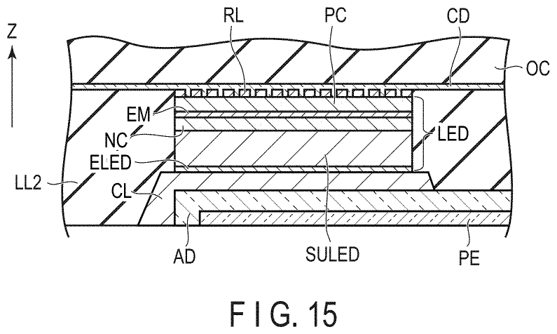

FIG. 15 is a cross-sectional view showing a light-emitting diode LED of another comparative example. In the light-emitting diode LED shown in FIG. 15, the area ratio between the region CA in which the resistive layer RL is absent and the region PA in which the resistive layer RL is present is the same as the present embodiment. In the present comparative example, however, the region PA in which the resistive layer RL is present is segmented as shown in FIG. 15.

By segmenting the region PA in which the resistive layer RL is present, the electric field distribution inside the light-emitting diode LED is averaged, and a difference in electric field intensity between the region PA in which the resistive layer RL is present and the region CA in which the resistive layer RL is absent is eliminated.

Since there is no difference in electric field intensity between the region PA in which the resistive layer RL is present and the region CA in which the resistive layer RL, the voltage applied to the emitting layer EM and the current flowing in the emitting layer EM are the same between the emitting layer EM close to the region PA in which the resistive layer RL is present and the emitting layer EM close to the region CA in which the resistive layer RL is absent.

Therefore, the effect described in FIG. 6 of when the light-emitting diodes LEDs having different voltage-current characteristics are simultaneously turned on cannot be obtained in the present comparative example.

As described above, the light-emitting diode LED of the present comparative example is close to a single light-emitting diode and does not produce an effect of improving the grayscale reproducibility of a low grayscale range.

While embodiments and modification examples of them have been described, the embodiments and the modification examples have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A display device comprising a display portion comprising a plurality of pixels, wherein
each of the pixels comprises an anode, a cathode, and a light-emitting diode disposed between the anode and the cathode,
the light-emitting diode comprises an emitting layer and a resistive layer partly overlapping the emitting layer in planar view, and
a width w of a region of the emitting layer which does not overlap the resistive layer and a thickness d of the light-emitting diode satisfy w/d>1.

2. The display device according to claim 1, wherein a region in which the emitting layer and the resistive layer do not overlap is disposed sandwiched between two regions in which the emitting layer and the resistive layer overlap.

3. The display device according to claim 1, wherein a region in which the emitting layer and the resistive layer overlap is disposed sandwiched between two regions in which the emitting layer and the resistive layer do not overlap.

4. The display device according to claim 1, wherein a region in which the emitting layer and the resistive layer do not overlap has a rectangular shape in planar view.

5. The display device according to claim 1, wherein a region in which the emitting layer and the resistive layer do not overlap has a circular shape in planar view.

6. The display device according to claim 1, wherein a region in which the emitting layer and the resistive layer do not overlap has a triangular shape or a polygonal shape with same or more sides than a pentagonal shape.

7. The display device according to claim 1, wherein the light-emitting diode comprises a light-emitting diode electrode, a light-emitting diode substrate on the light-emitting diode electrode, an n-type clad layer on the light-emitting diode substrate, the emitting layer on the n-type clad layer, a p-type clad layer on the emitting layer, and the resistive layer on the p-type clad layer.

8. The display device according to claim 1, wherein the light-emitting diode comprises a light-emitting diode electrode, a light-emitting diode substrate on the light-emitting diode electrode, the resistive layer on the light-emitting diode substrate, an n-type clad layer on the resistive layer, the emitting layer on the n-type clad layer, and a p-type clad layer on the emitting layer.

9. The display device according to claim 1, wherein the light-emitting diode comprises a light-emitting diode electrode, an n-type clad layer on the light-emitting diode electrode, the emitting layer on the n-type clad layer, a p-type clad layer on the emitting layer, the resistive layer on the p-type clad layer, and a light-emitting diode substrate on the resistive layer.

10. The display device according to claim 1, wherein the light-emitting diode comprises a light-emitting diode electrode, the resistive layer on the light-emitting diode electrode, an n-type clad layer on the resistive layer, the emitting layer on the n-type clad layer, a p-type clad layer on the emitting layer, and a light-emitting diode substrate on the p-type clad layer.

11. The display device according to claim 1, wherein the resistive layer is group III-IV compound semiconductor.

12. The display device according to claim 1, wherein
the pixels comprise a first pixel which emits red light, a second pixel which emits green light, and a third pixel which emits blue light,
the first pixel, the second pixel and the third pixel comprise a red light-emitting diode, a green light-emitting diode and a blue light-emitting diode, respectively, and
an area of a region in which the emitting layer of the red light-emitting diode and the resistive layer do not overlap is greater than an area of a region in which the emitting layer of the green light-emitting diode and the resistive layer do not overlap, but less than an area of a region in which the emitting layer of the blue light-emitting diode and the resistive layer do not overlap.

13. The display device according to claim 1, wherein
the pixels comprise a first pixel which emits red light, a second pixel which emits green light, and a third pixel which emits blue light,
the first pixel, the second pixel and the third pixel comprise a red light-emitting diode, a green light-emitting diode and a blue light-emitting diode, respectively, and
a width of a region in which the emitting layer of the red light-emitting diode and the resistive layer do not overlap is greater than a width of a region in which the emitting layer of the green light-emitting diode and the resistive layer do not overlap, but less than a width of a region in which the emitting layer of the blue light-emitting diode and the resistive layer do not overlap.

14. The display device according to claim 1, wherein
the pixels comprise a first pixel which emits red light, a second pixel which emits green light, and a third pixel which emits blue light,
the first pixel, the second pixel and the third pixel comprise a red light-emitting diode, a green light-emitting diode and a blue light-emitting diode, respectively, and
a thickness of the resistive layer of the red light-emitting diode is less than a thickness of the resistive layer of the green light-emitting diode, but greater than a thickness of the resistive layer of the blue light-emitting diode.
